(19) United States
(12) Patent Application Publication
(10) Pub. No.: US 2025/0004368 A1
(43) Pub. Date: Jan. 2, 2025

(54) A RELIEF PRECURSOR WITH VEGETABLE OILS AS PLASTICIZERS SUITABLE FOR PRINTING PLATES

(71) Applicant: XSYS GERMANY GmbH, Willstatt (DE)

(72) Inventors: Patrick-Kurt Dannecker, Willstätt (DE); Isabel Schlegel, Rastatt (DE)

(73) Assignee: XSYS Germany GmbH, Willstatt (NL)

(21) Appl. No.: 18/560,005

(22) PCT Filed: May 9, 2022
(86) PCT No.: PCT/EP2022/062430

§ 371 Date: Nov. 9, 2023

(30) Foreign Application Priority Data
May 12, 2021 (NL) 2028207

(51) Int. Cl. G03F 7/027; G03F 7/038; G03F 7/20; G03F 7/32; G03F 7/36; G03F 7/40

(52) U.S. Cl. CPC G03F 7/027; G03F 7/038; G03F 7/202; G03F 7/2022; G03F 7/325; G03F 7/36; G03F 7/40

(57) ABSTRACT

A relief precursor includes a dimensionally stable support, and at least one photopolymer layer including at least one binder, at least one photoinitiator or photoinitiating system, and at least one component with at least one unsaturated group and at least one plasticizer. The at least one plasticizer is a bio-based plasticizer, and has a UV transmission at 365 nm of a solution of 5 wt % plasticizer in n-hexane of higher than 15%.

### FIELD OF THE INVENTION

The present invention relates to a new relief precursor for flexographic printing elements, and the method for making such. The relief precursor is exposed to electromagnetic radiation in an imaging manner whereby exposed parts of a photosensitive layer change their solubility or melting behavior. Such flexographic printing elements are widely used in printing surfaces.

### BACKGROUND OF THE INVENTION

Flexographic printing elements are well known in the art and are especially useful for commercial printing on diverse products such as flexible plastic containers, cartons, plastic bags, boxes and envelopes. For the purpose of this specification, uncured plates to be used for preparing (cured) flexographic printing elements are referred to as relief precursors. Relief precursors typically comprise a layer prepared from a photo-curable polymer composition on the side that is to be used for printing, which may be selectively cured by exposing the photo-curable layer image-wise to light, e.g. UV light. The unexposed (uncured) parts of the layer may then be removed in developer baths, typically with an organic solvent or aqueous solutions. After drying and optional post exposure, the flexographic printing element is ready for use. It will be appreciated that the removal of uncured parts (developing) of the flexographic printing elements must be done in a precise manner. Any unintentional uncured residue that is left on the flexographic printing plate may lead to an unclear image on the flexographic printing plate, and, hence unclear prints.

Another way to prepare printing elements from a relief precursor is to expose the relief precursor to electromagnetic radiation in an imaging manner whereby exposed parts of a photosensitive layer change their solubility or melting behavior. The difference in melting or solubility allows selective removal of unexposed material to form a relief printing plate, which is then used to transfer ink from the printing plate to a printing substrate. Removal of unexposed material may be achieved by treating the precursor with a developing liquid, which dissolves unexposed material, or by a thermal treatment, which liquefies the unexposed material.

In EP-A-0332070 a method is described wherein unexposed material is dissolved in water, aqueous solutions or solvents and solvent mixtures, in combination with mechanical interaction by brushes in a so-called developing unit.

Another option is to remove liquefied material by continuously contacting it with an absorbing material. The absorbing developer material may be a non-woven of polyamide, polyester, cellulose or inorganic fibers onto which the softened material is adhering and subsequently removed. Such methods are described for example in U.S. Pat. Nos. 3,264,103, 5,175,072 or WO-A-9614603.

Even though the technology is on the market for quite a while, there are still some problems to be solved or properties to be improved. A disadvantage of the above described flexographic printing elements is that the printing results are not always consistent, as filling of negative lines and dots with ink occurs. Another disadvantage is that developing times are sometimes long and the efficiency of the manufacturing of the flexographic printing elements can still be improved.

Accordingly, there is a demand for flexographic printing elements that give more consistent printing results. There is furthermore a demand for shorter developing times.

### SUMMARY OF THE INVENTION

It is an object of the present invention to provide a relief precursor that increases the relief depth for both thermal or by solvent developing methods. A deeper relief enhances the printing result and prevents or reduces the filling of negative lines and dots with ink. It is a further object of the invention to provide a relief precursor that reduces the developing time and to improve efficiency of the manufacturing process of the relief plates. It is another object of the invention to reduce the anisotropy factor of the elastic modulus of the relief plates, such that the plates can be used in any orientation. It is yet another object of the present invention to develop a practical method for producing a relief structure that can be easily scaled up.

Accordingly, the present invention relates to a relief precursor as claimed in claim 1. In particular, a relief precursor is provided comprising a dimensionally stable support, at least one photopolymer layer comprising at least one binder, at least one photoinitiator or photoinitiating system, at least one component with at least one unsaturated group and at least one plasticizer, wherein the at least one plasticizer is a bio-based plasticizer, the plasticizer being characterized by a UV transmission at 365 nm of a solution of 5 wt % plasticizer in n-hexane of higher than 15%.

By using the bio-based plasticizer, flexographic printing elements can be produced with lower anisotropy. Furthermore, deep reliefs on (thermally developable) relief plates are being generated, resulting in more consistent printing results. It is furthermore easier to remove the non-polymerized material more evenly, which improves at the end the printing results. Another advantage is that to generate reliefs on thermally developable relief plates less development cycles are required. Further advantages are that resulting prints are better, there is less ink fill in by deeper negative elements, there is less non-woven or waste material. Furthermore, development times are shorter, and energy savings due to reduced temperature and/or development time are achieved. Also, by using the bio-based plasticizer, flexographic printing elements can be produced with less stress/damages to the support layer.

The present invention also relates to a method for producing a relief structure comprising the following steps:
a) providing of a relief precursor comprising a dimensionally stable support, a photopolymer layer comprising at least one binder, at least one photoinitiator or photoinitiating system, at least one component with at least one unsaturated group and at least one plasticizer wherein the at least one plasticizer is a bio-based plasticizer, the plasticizer being characterized by a UV transmission at 365 nm of a solution of 5 wt % plasticizer in n-hexane of higher than 15%;
b) imaging the relief precursor by ablation of a mask layer, by exposure through mask or by direct imaging;
c) exposing the imaged relief precursor with electromagnetic radiation to cure the imaged areas;
d) removing of the non-cured areas; and
e) optionally performing one or more steps of post treatment, post exposure, and/or detackifying.

### DETAILED DESCRIPTION OF THE INVENTION

Unless otherwise defined, all technical and scientific terms used herein have the same meaning as commonly understood by one of ordinary skill in the art, which this invention belongs. The terminology used in the description of the invention herein is for the purpose of describing particular embodiments only and is not intended to be limiting of the invention.

Thus in the present invention a relief precursor is provided comprising a dimensionally stable support, at least one photopolymer layer comprising at least one binder, at least one photoinitiator or photoinitiating system, at least one component with at least one unsaturated group and at least one plasticizer, wherein the at least one plasticizer is a bio-based plasticizer, the plasticizer being characterized by a UV transmission at 365 nm of a solution of 5 wt % plasticizer in n-hexane of higher than 15%. One of the advantages of this is that deep reliefs on (thermally developable) relief plates are being generated, resulting in more consistent printing results.

A relief precursor to be used with the claimed processes is described in the following: A relief precursor generally comprises a dimensionally stable support or a supporting layer made of a first material and an additional layer made of a second material, which is different from said first material. The dimensionally stable support may be a flexible metal, a natural or artificial polymer, paper or combinations thereof. Preferably, the dimensionally stable support is a flexible metal or polymer film or sheet. In case of a flexible metal, the supporting layer could comprise a thin film, a sieve like structure, a mesh like structure, a woven or non-woven structure or a combination thereof. Steel, copper, nickel or aluminum sheets are preferred and may be about 50 to 1000 μm thick. In case of a polymer film, the film is dimensionally stable but bendable and may be made for example from polyalkylenes, polyesters, polyethylene terephthalate, polybutylene terephthalate, polyamides und polycarbonates, polymers reinforced with woven, non-woven or layered fibers (e.g. glass fibers, Carbon fibers, polymer fibers) or combinations thereof. Preferably polyethylene and polyester foils are used and their thickness may be in the range of about 100 to 300 μm, preferably in the range of 100 to 200 μm.

The relief precursor preferably carries at least one further layer. For example, the further layer may be any one of the following: a direct engravable layer (e.g. by laser), a solvent or water developable layer, a thermally developable layer, a photosensitive layer, a combination of a photosensitive layer and a mask layer. More preferably, the further layer is an adhesion layer below the support, an adhesion layer between the support and a photopolymer layer or between any other layers, a barrier layer, a laser ablatable layer and/or a protective layer. Optionally there may be provided one or more further additional layers on top of further layer. Such one or more further additional layers may comprise a cover layer at the top of all other layers, which is removed before the imageable layer is imaged. The one or more further additional layers may comprise a relief layer, and an anti-halation layer between the supporting layer and the relief layer or at a side of the supporting layer, which is opposite of the relief layer. The one or more further additional layers may comprise a relief layer, an imageable layer, and one or more barrier layers between the relief layer and the imageable layer, which prevent diffusion of oxygen. Between the different layers described above one or more adhesion layers may be located, which ensure proper adhesion of the different layers.

The relief precursor comprises at least a photopolymer layer and may further comprise a mask layer. The mask layer may be ablated or changed in transparency during the treatment and forms a mask with transparent and non-transparent areas. Underneath of transparent areas of the mask the photosensitive layer undergoes a change in solubility and/or fluidity upon irradiation. The change is used to generate the relief by removing parts of the photosensitive layer in one or more subsequent steps. The change in solubility and/or fluidity may be achieved by photo-induced polymerization and/or crosslinking, rendering the irradiated areas less soluble and less meltable. In other cases the electromagnetic radiation may cause breaking of bonds or cleavage of protective groups rendering the irradiated areas more soluble and/or meltable. Preferably a process using photo-induced crosslinking and/or polymerization is used.

The relief precursor comprises a photopolymer layer comprising at least one photoinitiator or photoinitiating system. A photo-initiator is a compound, which upon irradiation with electromagnetic radiation may form a reactive species, which can start a polymerization reaction, a crosslinking reaction, a chain or bond scission reaction, which leads to a change of the solubility and/or meltability of the composition. Photo-initiators are known, which cleave and generate radicals, acids or bases. Such initiators are known to the person skilled in the art and described e.g. in: Bruce M. Monroe et al., Chemical Review, 93, 435 (1993), R. S. Davidson, Journal of Photochemistry and Biology A: Chemistry, 73, 81 (1993) M. Tsunooka et al., 25 Prog. Polym. Sci., 21, 1 (1996), F. D. Saeva, Topics in Current Chemistry, 1 56, 59 (1990), G. G. Maslak, Topics in Current Chemistry, 168, 1 (1993), H. B. Shuster et al., JAGS, 112, 6329 (1990) and I. D. F. Eaton et al., JAGS, 102, 3298 (1980), P. Fouassier and J. F. Rabek, Radiation Curing in Polymer Science and Technology, pages 77 to 117 (1993) or K. K. Dietliker, Photoinitiators for free Radical and Cationic Polymerisation, Chemistry & Technology of UV & EB Formulation for Coatings, Inks and Paints, Volume, 3, Sita Technology LTD, London 1991; or R. S. Davidson, Exploring the Science, technology and Applications of U.V. and E.B. Curing, Sita Technology LTD, London 1999. Further initiators are described in JP45-37377, JP44-86516, U.S. Pat. Nos. 3,567,453, 4,343,891, EP109772, EP109773, JP63138345, JP63142345, JP63142346, JP63143537, JP4642363, JP59152396, JP61151197, JP6341484, JP2249 and JP24705, JP626223, JPB6314340, JP1559174831, JP1304453 und JP1152109.

The photopolymer layer of the relief precursor comprises at least one binder. The binders according to the invention are linear, branched or dendritic polymers, which may be homopolymers or copolymers. Copolymers can be random, alternating or block copolymers. As binder, those polymers, which are either soluble, dispersible or emulsifiable in either aqueous solutions, organic solvents or combinations of both are used. Suitable polymeric binders are those conventionally used for the production of letterpress printing plates, such as completely or partially hydrolyzed polyvinyl esters, for example partially hydrolyzed polyvinyl acetates, polyvinyl alcohol derivatives, e.g. partially hydrolyzed vinyl acetate/alkylene oxide graft copolymers, or polyvinyl alcohols subsequently acrylated by a polymer-analogous reaction, as described, for example, in EP-A-0079514, EP-A-0224164 or EP-A-0059988, and mixtures thereof. Also suitable as polymeric binders are polyurethanes or polyamides, which are soluble in water or water/alcohol mixtures, as described, for example, in EP-A-00856472 or DE-A-1522444. For flexographic printing precursors elastomeric binders are used. The thermoplastic-elastomeric block copolymers comprise at least one block, which consists essentially of alkenylaromatics, and at least one block, which consists essentially of 1,3-dienes. The alkenylaromatics may be, for example, styrene, α-methylstyrene, or vinyltoluene. Styrene is preferable. The 1,3-dienes are preferably butadiene and/or isoprene. These block copolymers may be linear, branched, or radial block copolymers. Generally speaking, they are triblock copolymers of the A-B-A type, but they may also be diblock polymers of the A-B type, or may be polymers having a plurality of alternating elastomeric and thermoplastic blocks. A-B-A-B-A, for example. Mixtures of two or more different block copolymers may also be used. Commercial triblock copolymers frequently include certain fractions of diblock copolymers. The diene units may be 1,2- or 1,4-linked. Also possible for use, furthermore, are thermoplastic elastomeric block copolymers with styrene and blocks and a random styrene-butadiene middle block. Use may also be made, of course, of mixtures of two or more thermoplastic-elastomeric binders, provided that the properties of the relief-forming layer are not negatively impacted as a result. As well as the stated thermoplastic-elastomeric block copolymers, the photopolymerizable layer may also comprise further elastomeric binders other than the block copolymers. With additional binders of this kind, also called secondary binders, the properties of the photopolymerizable layer can be modified. Examples of a secondary binder are vinyltoluene-a-methylstyrene copolymers. These polymer binders account for in general from 20 to 98%, preferably from 50 to 90% by weight of the total amount of the layer.

The photopolymer layer comprises furthermore at least one component with at least one unsaturated group. Preferably, these components are reactive compounds or monomers, which are suitable for the preparation of the mixtures are those, which are polymerizable and are compatible with the binders. Useful monomers of this type generally have a boiling point above 100° C. They usually have a molecular weight of less than 3000 g/mol, preferably less than 2000 g/mol. More preferably, the ethylenically unsaturated monomers are used that ought to be compatible with the binders, and they have at least one polymerizable, ethylenically unsaturated group. As monomers it is possible in particular to use esters or amides of acrylic acid or methacrylic acid with mono- or polyfunctional alcohols, amines, aminoalcohols or hydroxyethers and hydroxyesters, esters of fumaric acid or maleic acid, and allyl compounds. Esters of acrylic acid or methacrylic acid are even more preferred. Preference is given to 1,4-butanediol diacrylate, 1,6-hexanediol diacrylate, 1,6-hexanediol dimethacrylate, 1,9-nonanediol diacrylate, or trimethylolpropane tri(meth)acrylate. Mixtures of different monomers can of course be used. The total amount of all the monomers used in the relief-forming layer together is generally 1 to 20 wt %, preferably 5 to 20 wt %, based in each case on the sum of all the constituents of the relief-forming layer. The amount of monomers having two ethylenically unsaturated groups is preferably 5 to 20 wt %, based on the sum of all constituents of the relief-forming layer, more preferably 8 to 18 wt %.

The photopolymer layer may comprise further components. The further components are selected from the group consisting of a further polymer, a filler, a plasticizer, an anti-blocking agent, a monomer, an additive (e.g. a stabilizer, a dye), a crosslinker, a binder, a color forming compound, a dye, a pigment, an antioxidant and combinations thereof.

The relief precursor comprises a photopolymer layer as described above and may furthermore comprise a mask layer, the mask layer comprising at least a compound capable of absorbing electromagnetic radiation and a component capable of being removed by ablation (also known as digital plate precursor). Preferably the mask layer is an integral layer of the relief precursor and is in direct contact with the photosensitive layer or with a functional layer disposed between photosensitive layer and mask layer. This functional layer is preferably a barrier layer and blocks oxygen. The mask layer may be imageable by ablation and removable by solvents or by thermal development. The mask layer is heated and removed by irradiation with high energy electromagnetic radiation, whereby an image wise structured mask is formed, which is used to transfer the structure onto the relief precursor. In order to do so the mask layer may be non-transparent in the UV region and absorb radiation in the VIS-IR region of the electromagnetic spectrum. The VIS-IR radiation may then be used to heat and ablate the layer. The optical density of the mask layer in the UV region between 330 and 420 nm is in the range of 1 to 5, preferably in the range of 1.5 to 4 and more preferably in the range of 2 to 4.

The layer thickness of the ablatable mask layer may be in the range of 0.1 to 5 μm, preferably 0.3 to 4 μm, more preferably 1 to 3 μm. The laser sensitivity of the mask layer (measured as energy needed to ablate 1 cm²) may be in the range of 0.1 to 10 J/cm², preferably in the range of 0.3 to 5 J/cm², most preferably in the range of 0.5 to 5 J/cm².

The photopolymer layer comprises at least one plasticizer, wherein the at least one plasticizer is a bio-based plasticizer. Bio-based plasticizers are at least partially derived from renewable, biological resources such as plants (e.g. agricultural crops or wood), microorganisms (e.g. algae or yeasts), or animals. Bio-based plasticizers are environmental friendly, often but not necessarily biodegradable. Bio-based materials may be chemically altered, or modified with synthetic compounds, to change for example physical and/or chemical properties. They then still remain bio-based materials. These plasticizers are generally used to maintain softness and flexibility at varying temperature ranges. These plasticizers can at least partly replace other plasticizers, like synthetic plasticizers. Many of the non-bio-based plasticizers, especially the so-called phthalates, are harmful to one's health and may affect the hormone balance. Others are mineral oil or polybutadiene based and not easily biodegradable. It is thus advantageous to at least partly replace them by bio-based plasticizers. We furthermore found that when bio-based plasticizers are being used for thermal development, a higher relief depth can be achieved for all concentrations investigated. Moreover, we found that the use of for example rapeseed oil instead of mineral oil allows for higher washout speeds and results in shorter process times. Preferably, the bio-based plasticizer is a vegetable oil, a fatty acid and/or a fatty acid ester of mono- or polyfunctional alcohols. More preferably, the bio-based plasticizer is one or more of rapeseed oil, sunflower oil, soybean oil, palm oil, palm kernel oil, coconut oil, medium-chain triglycerides (MCT) oil and/or linseed oil. Further examples are açaí oil, adeps lanae, ahiflower oil, algea oil, aloe vera, amaranth oil, apricot kernel oil, argan oil, avocado oil, babassu oil, baobab oil, beeswax, black cumin oil, black cumin seed oil, blackcurrant oil, borage oil, brazilnut oil, broccoliseed oil, calendula oil, camelina oil, candelilla wax, carnauba wax, castor oil, chia oil, chilean hazelnut oil, cocoa butter, corn oil, cotton seed oil, cupuaçu butter, evening primrose oil, fish oil, glycerol, grape seed oil, groundnut oil, hazelnut oil, hemp oil, high-oleic canola oil, high oleic soybean oil, high oleic sunflower oil, illipe butter, jatropha curcas oil, jojoba oil, kukuinut oil, lanolin, laurel oil, macadamia nut oil, mango butter, manketti oil, marula oil, meadowfoam seed oil, milk thistle oil, moringa oil, murumuru butter, mustardseed oil, olive oil, olus oil, omega-3-6-9-oil, palmolein, palm stearin, paradise nut oil, passionfruit seed oil, peach kernel oil, peanut oil, pecan nut oil, perilla oil, pistachio nut oil, plum kernel oil, pomegranate oil, poppyseed oil, pumpkin seed oil, rapeseed oil hydrogenated, raw wool grease, rice bran oil, rose hip kernel oil, sacha inchi oil, safflower oil, sal fat, sea buckthorn oil, sesame oil, shea butter, soybean oil hydrogenated, soybean oil partially hydrogenated, squalane, sunflower oil hydrogenated, sunflower wax, sumac wax, tallow, tamanu oil, walnut oil, wheat germ oil, wool fat, wool alcohols.

The composition and properties of vegetable oils and fats are highly dependent on many factors. The fatty acid composition and impurities in the oil influence chemical and physical properties such as the UV transmission, light transmission, Gardner Color and iodine value. Main influence factors are: crop type, growing region, breed, refining and processing (such as filtering, bleaching, neutralizing, deodorizing). Moreover, oil compositions and properties can be modified by blending, distillation, fractionation, hydrogenation, interesterification with chemical catalysts, interesterification with specific lipases, enzymatic enhancement, biological solutions, domestication of wild crops, conventional seed breeding, (intra-species) genetic engineering, lipids from micro-organisms or other unconventional sources. Depending on these factors, the chemical composition and properties of vegetable oils from different crop types can be more similar to one another than within one type of crop.

Within the same batch of oil, the properties may be dependent on the storage. A long storage time, a high storage temperature and/or contact with air and/or oxygen may lead to aging of the oil. Possible effects may be e.g. a decrease in the UV transmission, light transmission and iodine value or an increase in Gardner Color and hydroxyl value. Fresh and well-processed oils with a high UV transmission and/or high light transmission and/or low Gardner Color and/or low hydroxyl value are preferred compared to aged oils or crude vegetable oils with a low UV transmission and/or low light transmission and/or high Gardner Color and/or high hydroxyl value. Slow aging and storage over time can be accelerated by heating the oil under the influence of air.

The photopolymer layer comprises at least one plasticizer, wherein the at least one plasticizer is a bio-based plasticizer. Other plasticizers might also be present, it can thus be a mixture of 2 or more bio-based plasticizer, or a mixture of at least a bio-based plasticizer and conventional plasticizer(s). Thus, mixtures of different plasticizers may also be used, as long as at least one plasticizer is a bio-based plasticizer. Examples of the other suitable plasticizers encompass modified and unmodified natural oils and natural resins, such as high-boiling paraffinic, naphthenic or aromatic mineral oils, synthetic oligomers or resins such as oligostyrene, high-boiling esters, oligomeric styrene-butadiene copolymers, oligomeric alpha-methylstyrene/p-methylstyrene copolymers, liquid oligobutadienes, especially those having a molecular weight of 500 to 5000 g/mol, or liquid oligomeric acrylonitrile-butadiene copolymers or oligomeric ethylene-propyl-ene-diene copolymers. Preference is given to polybutadiene oils (liquid oligobutadienes), especially those having a molecular weight of 500 to 5000 g/mol, high-boiling aliphatic esters such as, in particular, alkyl esters of monocarboxylic and dicarboxylic acids, examples being stearates or adipates and mineral oils. Particularly preferred are high-boiling, substantially paraffinic and/or naphthenic mineral oils. It is possible, for example, to use what are called paraffin-base solvates and specialty oils. With mineral oils, the skilled person distinguishes between technical white oils, which may also include a very small aromatic content, and medical white oils, which are substantially free from aromatics. They are commercially available and equally well-suited. Particularly widespread as plasticizers are white oils or oligomeric plasticizers, such as, in particular, polybutadiene oils, carboxylic esters, phthalates. In this regard, reference may be made by way of example to EP 992 849 and EP 2 279 454. The amount of a plasticizer optionally present is determined by the skilled person according to the desired properties of the layer.

Preferably, the plasticizer is characterized by a UV transmission at 365 nm of a solution of 5 wt % plasticizer in n-hexane of higher than 30%, more preferably higher than 50%, more preferably higher than 60%.

Advantageously, the plasticizer is characterized by a light transmission in comparison to medium-chain triglycerides (MCT)-oil (=100% transmission) of higher than 78%. The measurement of the transparent MCT-oil, which is more resistant towards oxidation due to the lack of double bonds, was set as standard with 100% light transmission.

The plasticizer might be characterized by its Gardner Color. The Gardner Color Scale is a one-dimensional scale used to measure the shade of the color yellow. The Gardner scale and the APHA/Pt-Co/Hazen Color Scale overlap with the Gardner scale measuring higher concentrations of yellow color and the APHA scale measuring very low levels of yellow color. Colors of transparent liquids have been studied visually since the early 19th century. Changes in color can indicate contamination or impurities in the raw materials, process variations, or degradation of products over time. Advantageously, the plasticizer is characterized by a Gardner color lower than 7 according to ISO 4630:2015.

The plasticizer can also be characterized by its hydroxyl value. The hydroxyl value is defined as the number of milligrams of potassium hydroxide required to neutralize the acetic acid taken up on acetylation of one gram of a chemical substance that contains free hydroxyl groups. The hydroxyl value is a measure of the content of free hydroxyl groups in a chemical substance, usually expressed in units of the mass of potassium hydroxide (KOH) in milligrams equivalent to the hydroxyl content of one gram of the chemical substance. The analytical method used to determine hydroxyl value traditionally involves acetylation of the free hydroxyl groups of the substance with acetic anhydride in pyridine solvent. After completion of the reaction, water is added, and the remaining unreacted acetic anhydride is converted to acetic acid and measured by titration with potassium hydroxide. The hydroxyl value can then be calculated. Advantageously, the plasticizer is characterized by a hydroxyl value according to ASTM D1957-86 below 430, preferably below 250, even more preferably below 168.

The plasticizer can similarly be characterized by its iodine value. The iodine value (or iodine adsorption value or iodine number or iodine index, commonly abbreviated as IV) in chemistry is the mass of iodine in grams that is consumed by 100 grams of a chemical substance. Iodine numbers are often used to determine the degree of unsaturation in fats, oils and waxes. In fatty acids, unsaturation occurs mainly as double bonds, which are very reactive towards halogens, the iodine in this case. Thus, the higher the iodine value, the more unsaturated bonds contains the fat. The plasticizer to be used in the relief precursor of the invention preferably has an iodine value according to ISO 3961:2018 below 200, more preferably below 150.

The plasticizer can furthermore be characterized by its Hansen solubility parameter δt. The Hansen solubility is based on the idea that like dissolves like where one molecule is defined as being ‘like’ another if it bonds to itself in a similar way. A description of the determination of the Hansen solubility parameters can be found in J. Brandrup, E. H. Immergut, E. A. Grulke, Polymer Handbook 4^{th} ed., Wiley, New York, 1999, pp. VII/675-VII/714. Advantageously, the plasticizer has a Hansen solubility parameter δt in the range of from 16.0 up to 20.5, more preferably in the range of from 16.0 to 17.5.

The amount of a plasticizer optionally present is determined by the skilled person according to the desired properties of the layer. The concentration of the plasticizer in the photopolymer layer is preferably in the range of from 3 up to 70 wt %, more preferably in the range of from 5 up to 65 wt %, even more preferably in the range of from 10 up to 65 wt %, most preferably in the range of from 20 up to 60 wt %, based on the total weight of the photopolymer layer.

A thermal treatment may be utilized, for example, to initiate and/or to complete reactions, to increase the mechanical and/or thermal stability of the relief structure, and to remove volatile constituents. For the thermal treatment it is possible to use the known techniques, such as heating using heated gases or liquids, IR radiation, and any desired combinations thereof, for example. In these contexts it is possible to employ ovens, blowers, lamps, and any desired combinations thereof. In addition to disbanding, surface modifications can also be accomplished by the treatment with gases, plasma and/or liquids, especially if in addition there are reactive substances employed as well. In the present invention, it is preferred that a developing step is performed by thermal treatment and removal of the liquefied portion.

The present invention is also directed to a method for producing a relief structure comprising the following steps:
a) providing of a relief precursor comprising a dimensionally stable support, a photopolymer layer comprising at least one binder, at least one photoinitiator or photoinitiating system, at least one component with at least one unsaturated group and at least one plasticizer wherein the at least one plasticizer is a bio-based plasticizer, the plasticizer being characterized by a UV transmission at 365 nm of a solution of 5 wt % plasticizer in n-hexane of higher than 15%;
b) imaging the relief precursor by ablation of a mask layer, by exposure through mask or by direct imaging;
c) exposing the imaged relief precursor with electromagnetic radiation to cure the imaged areas;
d) removing of the non-cured areas; and
e) optionally performing one or more steps of post treatment, post exposure, and/or detackifying.

In step b) of the method for producing a relief structure, the relief precursor is imaged by ablation of a mask layer, by exposure through mask or by direct imaging. The mask layer can be a separate layer, which is applied to the relief precursor following the removal of a protective layer that may possibly be present, or an integral layer of the precursor, which is in contact with the relief layer or one of the optional layers above the relief layer, and is covered by a protective layer that may possibly be present.

The mask layer can also be a commercially available negative, which, for example, can be produced by means of photographic methods based on silver halide chemistry. The mask layer can be a composite layer material in which, by means of image-based exposure, transparent layers are produced in an otherwise non-transparent layer, as described, for example in EP 3 139 210 A1, EP 1 735 664 B1, EP 2987 030, A1 EP 2 313 270 B1. This can be carried out by ablation of a non-transparent layer on a transparent carrier layer, as described, for example, in U.S. Pat. No. 6,916,596, EP 816 920 B1, or by selective application of a non-transparent layer to a transparent carrier layer, as described in EP 992 846 B1, or written directly onto the relief-forming layer, such as, for example, by printing with a non-transparent ink by means of ink-jet, as described, for example, in EP 1 195 645 A1.

Image wise removal of the mask layer is preferably performed using ablation technology. As a rule, the electromagnetic radiation for ablating the mask will generally be radiation having a wavelength in the range from 300 nm to 20000 nm, preferably in the range from 500 nm to 20000 nm, particularly preferably in the range from 800 nm to 15000 nm, very particularly preferably in the range from 800 nm to 11000 nm. In addition to solid-body lasers, gas lasers or fiber lasers can also be used. Preferably, in laser ablation, use is made of Nd:YAG lasers (1064 nm) or CO2-lasers (9400 nm and 10600 nm). For the selective removal of the mask layer, one or more laser beams are controlled such that the desired printing image is produced.

The direct image exposure can be achieved in that the regions to be cross-linked are exposed selectively. This can be achieved, for example, with one or more laser beams, which are controlled appropriately, by the use of monitors in which specific image points, which emit radiation are activated, by using movable LED strips, by means of LED arrays, in which individual LEDs are switched on and off specifically, by means of the use of electronically controllable masks, in which image points, which allow the radiation from a radiation source to pass are switched to transparent, by means of the use of projection systems, in which by means of appropriate orientation of mirrors, image points are exposed to radiation from a radiation source, or combinations thereof. Preferably, the direct exposure is carried out by means of controlled laser beams or projection systems having mirrors. The absorption spectra of the initiators or initiator systems and the emission spectra of the radiation sources must at least partly overlap.

The wavelength of the electromagnetic radiation lies in the range from 200 nm to 20000 nm, preferably in the range from 250 nm to 1100 nm, particularly preferably in the UV range, very particularly preferably in the range from 300 nm to 450 nm. Besides broadband irradiation of the electromagnetic radiation, it can be advantageous to use narrow-band or monochromatic wavelength ranges, such as can be produced by using appropriate filters, lasers or light emitting diodes (LEDs). In these cases, wavelengths of 350 nm, 365 nm, 385 nm, 395 nm, 400 nm, 405 nm, 532 nm, 830 nm, 1064 nm (and about 5 nm to 10 nm below and/or above this), on their own or in combination, are preferred.

In step c) of the method for producing a relief structure, the imaged relief precursor is exposed with electromagnetic radiation to cure the imaged areas. The relief is generated by exposure with electromagnetic radiation through a mask film. On exposure, the exposed regions undergo crosslinking, whereas the unexposed regions of the precursor remain soluble or liquefiable and are removed by appropriate methods. Where an imaged mask is present, irradiation may take place extensively, or, if operating without a mask layer, irradiation may take place in an imaging way over a small area (virtually dotwise) by means of guided laser beams or positionally resolved projection of electromagnetic radiation. The wavelength of the electromagnetic waves irradiated in this case is in the range from 200 to 2000 nm, preferably in the range from 200 to 450 nm, more preferably in the range form 250 nm to 405 nm. The irradiation may take place continuously or in pulsed form or in a plurality of short periods with continuous radiation. In addition to broadband radiation of the electromagnetic waves, it may be advantageous to use narrow-band or monochromatic wavelength ranges, as can be generated using appropriate filters, lasers or light-emitting diodes (LEDs). In these cases, wavelengths in the ranges 350, 365, 385, 395, 400, 405, 532, 830, 1064 nm individually (and about 5-10 nm above and/or below) or as combinations are preferred. The intensity of the radiation here may be varied over a wide range, ensuring that a dose is used, which is sufficient to cure the radiation-curable layer sufficiently for the later development procedure. The radiation-induced reaction, possibly after further thermal treatments, must be sufficiently advanced that the exposed regions of the radiation-sensitive layer become at least partially insoluble and therefore cannot be removed in the developing step. The intensity and dose of the radiation are dependent on the reactivity of the formulation and on the duration and efficiency of the developing. The intensity of the radiation is in the range from 1 to 15000 mW/cm², preferably in the range from 5 to 5000 mW/cm², more preferably in the range from 10 to 1000 mW/cm². The dose of the radiation is in a range from 0.3 to 6000 J/cm², preferably in a range from 3 to 100 J/cm², more preferably in the range from 6 to 20 J/cm². Exposure to the energy source may also be carried out in an inert atmosphere, such as in noble gases, CO2 and/or nitrogen, or under a liquid, which does not damage the relief precursor. Exposure through the mask can be done by using optical devices, for example for beam widening, by a two-dimensional arrangement of multiple point-like or linear sources (for example light guides, emitters), such as fluorescent strip lamps arranged beside one another, by moving a linear source or an elongated arrangement of LEDs (array) relative to the relief precursor, for example by a uniform movement of LEDs or combinations thereof. Preferably, fluorescent strip lamps arranged beside one another or a relative movement between one or more LED strips and the relief precursor is used.

The irradiation can be carried out continuously, in a pulsed manner or in multiple short periods with continuous radiation.

In step d) of the method for producing a relief structure, the non-cured areas are removed. The removal of the non-cured areas of the precursor is preferably performed by treatment with heat and a developing material configured to adsorb non-cured material. More preferably, in step d) the precursor is heated to a temperature in the range of 70 to 200° C., preferably in the range of 80 to 180° C., more preferably in the range of 90 to 165° C. The heating of the exposed relief precursor may be carried out by all of the techniques known to the skilled person, such as, for example, by irradiation with IR light, the action of hot gases (e.g., air), using hot rollers, or any desired combinations thereof. To remove the (viscously) liquid regions it is possible to employ all techniques and processes familiar to the skilled person, such as, for example, blowing, suction, dabbing, blasting (with particles and/or droplets), stripping, wiping, transfer to a developing medium, and any desired combinations thereof. Preferably the liquid material is taken up (absorbed and/or adsorbed) by a developing medium, which is contacted continuously with the heated surface of the relief precursor. The procedure is repeated until the desired relief height is reached. Developing media, which can be utilized are papers, woven and nonwoven fabrics, and films, which are able to take up the liquefied material and may consist of natural fibers and/or polymeric fibers. Preference is given to using nonwovens or non-woven fiber webs of polymers such as celluloses, cotton, polyesters, polyamides, polyurethanes, and any desired combinations thereof, which are stable at the temperatures employed when developing.

Alternatively, in step d) the precursor is treated with a developing liquid to dissolve non-cured material. The techniques applied in this development step may be all of those familiar to the skilled person. The solvents or mixtures thereof, the aqueous solutions, and the aqueous-organic solvent mixtures may comprise auxiliaries, which stabilize the formulation and/or increase the solubility of the components of the non-crosslinked regions. Examples of such auxiliaries are emulsifiers, surfactants, salts, acids, bases, stabilizers, corrosion inhibitors, and suitable combinations thereof. For development with these solutions, it is possible to use all of the techniques known to the skilled person, such as, for example, dipping, washing or spraying with the developing medium, brushing in the presence of developing medium, and suitable combinations thereof. Preference is given to developing with neutral aqueous solutions or water, with removal assisted by means of rotating brushes or a plush web. Another way of influencing the development is to control the temperature of the developing medium and to accelerate the development by raising the temperature, for example. In this step, it is also possible for further layers still present on the radiation-sensitive layer to be removed, if these layers can be detached during development and sufficiently dissolved and/or dispersed in the developer medium.

In step e) of the method for producing a relief structure, optionally one or more steps of post treatment, post exposure, and/or detackifying are performed. These include, for example, a thermal treatment, a drying, a treatment with electromagnetic rays, with plasma, with gases or with liquids, attachment of identification features, cutting to format, coating, and any desired combinations thereof. A thermal treatment may be utilized, for example, to initiate and/or to complete reactions, to increase the mechanical and/or thermal stability of the relief structure, and to remove volatile constituents. For the thermal treatment, it is possible to use the known techniques, such as heating using heated gases or liquids, IR radiation, and any desired combinations thereof, for example. In these contexts, it is possible to employ ovens, blowers, lamps, and any desired combinations thereof. In addition to disbanding, surface modifications can also be accomplished by the treatment with gases, plasma and/or liquids, especially if in addition there are reactive substances employed as well. Treatment with electromagnetic radiation may be used, for example, for the purpose of detackifying the surfaces of the relief structure, and triggering and/or completing polymerization reactions and/or crosslinking reactions. The wavelength of the irradiated electromagnetic waves in this case is in the range from 200 to 2000 nm.

The following, non-limiting examples are provided to illustrate the invention.

### Determination of UV Transmission:

The UV transmission at 365 nm was measured in n-hexane with a plasticizer concentration of 5 by weight in a macro-cuvette 110-QS, 10 mm. The UV/Vis spectrum was recorded on a Varian Cary 50, scan Software version: 02.00, beam mode: Dual Beam. A baseline correction was performed with a blank sample of pure n-hexane and applied with the integrated software of the instrument.

### Determination of the Light Transmission:

The pure oil was filled in a macro-cuvette 110-QS, 10 mm and the light transmission measured by putting the cuvette in a densitometer Gretag Macbeth D 200 II (measuring tube: V (2), measuring aperture: 3 mm diameter) and pressing the probe head on the macro-cuvette. The measurement of the transparent MCT-oil, which is resistant towards oxidation due to the lack of double bonds, was set as standard with 100% transmission. The mean value of 3 measurements was determined.

### Example 1

As an example of the present invention, materials in plate form were produced: A photopolymeric mixture containing
an SIS triblock block copolymer with a styrene content of 14 to 15%, a diblock fraction of around 26% and a vinyl group content of 7-8% in parts by weight as indicated in table 1;
5 parts by weight of hexanediol diacrylate,
2.5 parts by weight of benzil dimethyl ketal as photoinitiator, plasticizers in parts by weight as indicated in table 1, and
1.5 parts by weight of further constituents such as inhibitors and dyes,
   was melted at elevated temperatures (120 to 180° C.) in an extruder and calendared via a slot die between a cover film with laser-ablatable mask layer having a thickness of 105 μm and a carrier film having a thickness of 125 μm, thus giving the relief precursor (photopolymer+films) with a total thickness of 4040 μm.

### Thermal Development:

The relief precursor was exposed from the backside through the carrier foil with UVA light for 100 s (machine type: Combi FIII, UV output 16 mW/cm²). The laser ablatable mask on the front side was imaged with a Xeikon TfxX 20 laser (rotation 8.5 U/s, power 35 W (100%)) to form a square 20 cm×20 cm with a frame of 4.5 cm in a fashion, that the mask layer is still present in the middle, while it is removed in the frame part. The plate was irradiated with UVA light from the front side for 15 minutes (machine type: Combi FIII, UV output 16 mW/cm²). Non-polymerized material and residual black mask layer were removed by thermal development using an Xpress thermal developer (Flint Group). 10 passes at a speed of 0.7 inch/s were used, whereby the temperature was set to 162.8° C. (325° F.), the IR intensity was set to 40%, the blower intensity was set to 25%, the developer roll speed was set to 100%. During the first 4 passes, the pressure was set to 60 psi, followed by 5 passes at 80 psi and one final pass at 40 psi. After development, the area, which was covered by the black mask layer forms the “floor”, which is lower than the exposed area, which forms the “relief”. The floor thickness was measured in the middle at 9 different spots and the mean value was determined. The cliché thickness was measured at 5 different spots on the frame and the mean value was determined. The relief depth was calculated by subtracting the floor thickness from the cliché thickness and is given in table 1.

### Solvent Development:

For solvent development, a flowline FIII system with nylosolv A as solvent and a solid content of 4.8-5.1%, a brush height setting of 1.5 mm and a solvent temperature of 35° C. was used. Afterwards, the plates were dried at 60° C. for 2 h. The washout speed to achieve a washout depth of 1700 μm was determined according to Section “3.2 Determination of plate processing times” in the Nyloflex®UserGuide, page 16, version October 2007.

TABLE 1
composition of materials in plate form and the measured properties of example 1

| | A1 | B1 | C1 | A2 | B2 | C2 |
|---|---|---|---|---|---|---|
| Plasticizer | Mineral | Mineral | Mineral | Rapeseed | Rapeseed | Rapeseed |
| | oil | oil | oil | oil | oil | oil |
| Plasticizer content [%] | 21.7 | 27.3 | 32.9 | 21.7 | 27.3 | 32.9 |
| Rubber content [%] | 69.3 | 63.7 | 58.1 | 69.3 | 63.7 | 58.1 |
| Cliche thickness [μm] | 4002 | 3978 | 3971 | 3972 | 4058 | 4040 |
| Relief depth thermal [μm] | 828 | 974 | 964 | 1205 | 1336 | 1376 |
| Washout speed [mm/min] | 140 | 155 | 170 | 150 | 160 | 180 |
| Washout time [min] | 5.6 | 5.1 | 4.6 | 5.2 | 4.9 | 4.4 |

From the results presented in table 1, it can be concluded that for thermal development, a higher relief depth can be achieved when using a vegetable oil (rapeseed oil) for all concentrations investigated. Moreover, it becomes clear that using rapeseed oil instead of mineral oil allows higher washout speeds and results in shorter process times.

### Example 2

Materials in plate form were produced with the following composition:

A photopolymeric mixture containing:
64.4 parts by weight of a SBS triblock copolymer with a styrene content of 25% and a diblock fraction of around 10% as binder,
10 parts by weight of hexanediol diacrylate,
2.0 parts by weight of benzil dimethyl ketal as photoinitiator,
21 parts by weight plasticizer, and
2.6 parts by weight of further constituents such as inhibitors and dyes.

The mixture was melted at elevated temperatures (120 to 180° C.) in an extruder and calendared via a slot die between a cover film with laser-ablatable mask layer having a thickness of 105 μm and a carrier film having a thickness of 175 μm, thus giving the relief precursor (photopolymer+films) with a total thickness of 1240 μm.

### Thermal Development:

The plate processing and evaluation of relief depths was performed as in example 1. The backside exposure was reduced to 10 s. The conditions of the thermal development were varied: 1 pass at a speed of 0.7 inch/s was used, whereby the temperature was set to 143.3° C. (290° F.), the IR intensity was set to 40%, the blower intensity was set to 25%, the developer roll speed was set to 100% and the pressure was set to 60 psi. The results of the materials are in Table 2.

### Solvent Development:

Solvent development was performed as in example 1 with a target washout depth of 900 μm and a brush height setting of 0 mm. The results of the materials are in Table 2.

### Anisotropic Factor:

The anisotropic factor was determined by stress-strain measurements with a zwickiLine universal testing machine and a load cell of with a nominal force of 200 N. Test specimens (size 5 A, according to ISO 527-2:1996) were prepared by stamping of a exposed plate (machine type: Combi FIII, UV output 16 mW/cm²) with removable PET foils. Two measurements were performed, one measurement longitudinally and one measurement transversely with respect to the extrusion direction of the plate. The stress at 125% strain was measured. To obtain the anisotropic factor, the stress longitudinally was divided by the stress transversely. The results of the materials are in Table 2.

TABLE 2
composition of materials in plate form and
the measured properties of example 2

| | A | B | C |
|---|---|---|---|
| Plasticizer | Polybutadiene | Rapeseed | Mineral |
| | | oil | oil |
| Cliché thickness [μm] | 1142 | 1137 | 1138 |
| Relief depth thermal [μm] | 89 | 225 | 51 |
| Washout speed [mm/min] | 200 | 210 | 200 |
| Washout time [min] | 3.9 | 3.7 | 3.9 |
| Washing depth 210 mm/min [μm] | 841 | 866 | 857 |
| Anisotropic factor | 1.0 | 1.0 | 1.1 |

From the results presented in table 2, it can be concluded that for thermal development, a higher relief depth can be achieved when using a vegetable oil (rapeseed oil) compared to mineral oil or polybutadiene. Moreover, it becomes clear that using rapeseed oil instead of mineral oil or polybutadiene allows higher washout speeds, results in shorter process times and gives higher washing depths.

Additionally, the anisotropic factor of the plate with mineral oil as plasticizers is higher than the anisotropic factor of the plates with polybutadiene or rapeseed oil. An anisotropic factor of 1.0 is desired, which means that the elastic behavior of the plate is independent of its orientation.

### Example 3

Materials in plate form were produced with the following composition: A photopolymeric mixture containing:
45.4 parts by weight of a SBS triblock copolymer with a styrene content of 31% and a diblock fraction of around 14% as binder,
6.5 parts by weight of hexanediol diacrylate,
1.4 parts by weight of benzil dimethyl ketal as photoinitiator,
26.2 parts by weight mineral oil as first plasticizer,
19.5 parts by weight of a second plasticizer, and
1.0 parts by weight of further constituents such as inhibitors and dyes.

The mixture was melted at elevated temperatures (120 to 180° C.) in an extruder and calendared via a slot die between a cover film with laser-ablatable mask layer having a thickness of 105 μm and a carrier film having a thickness of 125 μm, thus giving the relief precursor (photopolymer+films) with a total thickness of 3280 μm.

### Thermal Development:

The plate processing and evaluation of relief depths and thermal development was performed as in example 1. The results of the materials are in Table 3.

### Solvent Development:

Solvent development was performed as in example 1 with a target washout depth of 1200 μm. The results of the materials are in Table 3.

### Depth of the 400 μm Negative Dot:

To evaluate the depth of negative elements, the test motive contains a dot with 400 μm diameter. To achieve good print results, typically a higher depth of negative elements is desirable. The depth measurement was performed with a Dot Check WH 360.

TABLE 3
composition of materials in plate form and
the measured properties of example 3

| | A | B |
|---|---|---|
| Plasticizer | Polybutadiene | Rapeseed oil |
| Cliché thickness [μm] | 3217 | 3180 |
| Relief depth thermal [μm] | 684 | 915 |
| Washout speed [mm/min] | 150 | 155 |
| Washout time [min] | 5.2 | 5.1 |
| Depth 400 μm negative dot [μm] | 178 | 182 |

From the results presented in table 3, it can be concluded that for thermal development, a higher relief depth can be achieved when using a vegetable oil (rapeseed oil) compared to polybutadiene.

Moreover, it becomes clear that using rapeseed oil instead of polybutadiene allows higher washout speeds and results in shorter process times. Additionally the depth of a negative dot increased when using the rapeseed oil.

### Example 4

Materials in plate form were produced with the following composition: A photopolymeric mixture containing:
58.0 parts by weight of a SBS triblock copolymer with a styrene content of 30%, no diblock as binder,
7.5 parts by weight of hexanediol diacrylate,
2.0 parts by weight of benzil dimethyl ketal as photoinitiator,
31 parts by weight plasticizer (A: polybutadiene, B: rapeseed oil), and
1.5 parts by weight of further constituents such as inhibitors and dyes.

The mixture was melted at elevated temperatures (120 to 180° C.) in an extruder and calendared via a slot die between a cover film with laser-ablatable mask layer having a thickness of 105 μm and a carrier film having a thickness of 175 μm, thus giving the relief precursor (photopolymer+films) with a total thickness of 1240 μm.

### Thermal Development:

The plate processing and evaluation of relief depths and thermal development were performed as in example 2. The results of the materials are in Table 4.

### Solvent Development:

Solvent development was performed as in example 2. The results of the materials are in Table 4.

TABLE 4
composition of materials in plate form and
the measured properties of example 4

| | A | B |
|---|---|---|
| Plasticizer | Polybutadiene | Rapeseed oil |
| Cliché thickness [μm] | 1161 | 1167 |
| Relief depth thermal [μm] | 156 | 201 |
| Washout speed [mm/min] | 210 | 220 |
| Washout time [min] | 3.7 | 3.6 |
| Washing depth 250 mm/min [μm] | 729 | 791 |
| Depth 400 μm negative dot [μm] | 202 | 213 |

From the results presented in table 4, it can be concluded that for thermal development, a higher relief depth can be achieved when using a vegetable oil (rapeseed oil) compared to polybutadiene. Moreover, it becomes clear that using rapeseed oil instead of polybutadiene allows higher washout speeds and results in shorter process times. Additionally the washing depth and the depth of a negative dot are increased when using a vegetable oil.

### Example 5

Materials in plate form were produced with the following composition:

A photopolymeric mixture containing the same ratios and components as described in example 2 was obtained by mixing the components in solution (solvent: toluene, solvent content: 55 parts by weight) at reflux. The plasticizer was varied as described in table 5. The mixture was stirred until a homogeneous solution was obtained. After cooling down to room temperature, the solution was cast on a carrier film having a thickness of 175 μm. A layer was formed by distributing the solution evenly with a doctor blade and a gap of 3160 μm. The layer was dried at 20° C. for 15 h and afterwards at 65° C. for 4 h to evaporate the solvent. A cover film with laser-ablatable mask layer having a thickness of 105 μm was laminated on top with a heated roller (110° C.) giving the relief precursor (photopolymer+films) with a total thickness of 1200-1300 μm.

With castor oil, plates could not be produced due to incompatibility with the formulation as an oil film was observed after the photopolymer layer cooled down to room temperature.

### Thermal Development:

The plate processing and evaluation of relief depths and thermal development was performed as in example 2. The results of the materials are in Table 5.

### Solvent Development:

Solvent development was performed as in example 2. The results of the materials are in Table 5.

### Backside Exposure:

The backside exposure time in order to achieve a relief depth of 700 μm for solvent development was determined on a Combi FIII, UV output 16 mW/cm² according to section “3.2 Determination of plate processing times” in the Nyloflex®UserGuide, page 17, version October 2007.

TABLE 5
composition of materials in plate form and the measured properties of example 5

| | A | B | C | D | E |
|---|---|---|---|---|---|
| Plasticizer | Polybutadiene | Rapeseed | Rapeseed | Sunflower | Soybean |
| | | oil | oil aged | oil | oil |
| Cliche thickness [μm] | 1244 | 1262 | 1156 | 1285 | 1288 |
| Relief depth thermal[μm] | 31 | 215 | 4382 | 140 | 122 |
| Washout speed [mm/min] | 200 | 210 | 190 | 210 | 210 |
| Washout time [min] | 3.9 | 3.7 | 4.1 | 3.7 | 3.7 |
| Washout depth 200 | 891 | 940 | 830 | 937 | 957 |
| mm/min [μm] | | | | | |
| UV Transmission of | 96.1 | 91.5 | 15.2 | 94.5 | 91.6 |
| plasticizer at 365 nm | | | | | |
| 5 wt % in n-hexane [%] | | | | | |
| Backside exposure [s] | 28 | 45 | 55 | 45 | 55 |
| Iodine value | —¹ | 105-126 | —¹ | 120-140 | 180-200 |
| Light transmission [%] | 100 | 99 | 78 | 100 | 97 |
| Depth 400 μm negative dot | 197 | 211 | —² | 216 | 207 |
| [μm] | | | | | |
| Hansen solubility | 17.1 | 16.9 | —¹ | 16.7 | 16.2 |
| parameter | | | | | |

| | F | G | H | I | J | K |
|---|---|---|---|---|---|---|
| Plasticizer | Palm oil | Palm | Coconut | MCT | Linseed | HO- |
| | | kernel | oil | oil | oil | sunflower |
| | | oil | | | | oil |
| Cliche thickness [μm] | 1290 | 1302 | 1257 | 1284 | 1258 | 1165 |
| Relief depth thermal | 119 | 121 | 211 | 338 | 209 | 137 |
| [μm] | | | | | | |
| Washout speed | 210 | 210 | 200 | 210 | 210 | 200 |
| [mm/min] | | | | | | |
| Washout time [min] | 3.7 | 3.7 | 3.9 | 3.7 | 3.7 | 3.9 |
| Washout depth 200 | 930 | 923 | 901 | 924 | —³ | 904 |
| mm/min [μm] | | | | | | |
| UV Transmission of | 84.2 | 96.1 | 95.1 | 96.7 | 89.2 | 93.0 |
| plasticizer at 365 nm 5 | | | | | | |
| wt % in n-hexane [%] | | | | | | |
| Backside exposure [s] | 25 | 15 | 15 | 12 | 80 | 25 |
| Iodine value | 50-57 | 13-23 | 7-12 | 0-1 | 186-194 | 78-90 |
| Gardner color | —¹ | —¹ | —¹ | —¹ | <6 | — |
| Light transmission [%] | —⁴ | —⁴ | —⁴ | 100 | 92 | 99 |
| Depth 400 μm negative | 152 | 203 | 207 | 196 | 220 | 209 |
| dot | | | | | | |
| Hansen solubility | 18.3 | —¹ | 17.4 | 20.0 | 16.4 | —¹ |
| parameter | | | | | | |

¹Not available.
²Development of digital plate not possible due to incompatibility of the oil and insufficient mask layer adhesion. Determination of relief depth by following the procedure of the thermal development as in example 2 and covering the middle of the frame with a metal plate during exposure instead of the mask layer.
³Washout completely down to carrier foil.
⁴Not measured, solid at room temperature.

From the results presented in table 5, it can be concluded that for thermal development, a higher relief depth can be achieved when using a vegetable oil (rapeseed oil rapeseed oil aged, sunflower oil, soybean oil, palm oil, palm kernel oil, coconut oil, MCT oil, linseed oil) compared to polybutadiene. Moreover, it becomes clear that using a vegetable oil instead of polybutadiene allows higher washout speeds, results in shorter process times and the depth of a negative dot is increased. The UV transmission of most of the vegetable oils correlates with the backside exposure time and a high transmission is preferred. Palm oil and rapeseed oil aged seem to be exceptions.

### Example 6

Production of materials in plate form: A photopolymeric mixture containing
75.5 parts by weight of a SIS triblock copolymer with a styrene content of 19%, 30% diblock as binder,
5 parts by weight of a vinyltoluene-methylstyrene copolymer (CAS: 9017-27-0),
6.7 parts by weight of hexanediol diacrylate,
3.3 parts by weight of hexanediol dimethacylate,
2.5 parts by weight of lauryl acrylate,
2.5 parts by weight of benzil dimethyl ketal as photoinitiator,
3 parts by weight plasticizer (A: mineral oil, B: rapeseed oil), and
1.5 parts by weight of further constituents such as inhibitors and dyes,
   was melted at elevated temperatures (120 to 180° C.) in an extruder and calendared via a slot die between a cover film with laser-ablatable mask layer having a thickness of 105 μm and a carrier film having a thickness of 175 μm, thus giving the relief precursor (photopolymer+films) with a total thickness of 1

TABLE 6
composition of materials in plate form and
the measured properties of example 6

| | A | B |
|---|---|---|
| Plasticizer | Mineral oil | Rapeseed oil |
| Cliché thickness [μm] | 1136 | 1141 |
| Relief depth thermal [μm] | 11 | 15 |
| Washout speed [mm/min] | 235 | 250 |
| Washout time [min] | 3.3 | 3.1 |
| Washing depth 240 mm/min [μm] | 874 | 929 |
| Anisotropic factor | 2.23 | 1.72 |

From the results presented in table 6, it can be concluded that for thermal development, a slightly higher relief depth can be achieved when using even a small amount (3%) of a vegetable oil. Moreover, a higher washout depth can be achieved and the anisotropic behavior of the plate is significantly reduced.

### Example 7

Materials in plate form were produced as in example 5.

### Thermal Development:

The plate processing and evaluation of relief depths and thermal development was performed as in example 2. The results of the materials are in Table 7.

### Solvent Development:

Solvent development was performed as in example 2. The results of the materials are in Table 7.

### Backside Exposure:

The backside exposure time in order to achieve a relief depth of 700 μm for solvent development was determined on a Combi FIII, UV output 16 mW/cm² according to section “3.2 Determination of plate processing times” in the Nyloflex®UserGuide, page 17, version October 2007.

TABLE 7
composition of materials in plate form and the measured properties of example 7

| | A | B | C | D | E | F | G |
|---|---|---|---|---|---|---|---|
| Plasticizer | Sunflower | Sunflower | Soybean | Soybean | Linseed | Linseed | Linseed |
| | oil | oil | oil | oil | oil | oil | oil |
| | | aged⁴ | | aged⁴ | | aged | aged⁴ |
| | | | | | | 5 h⁴ | |
| Cliche thickness [μm] | 1285 | 1139 | 1288 | 1202 | 1258 | 1204 | —¹ |
| Washout speed [mm/min] | 210 | 210 | 210 | 210 | 210 | 210 | —¹ |
| Washout time [min] | 3.7 | 3.7 | 3.7 | 3.7 | 3.7 | 3.7 | —¹ |
| Washout depth 200 | 937 | —³ | 957 | —³ | —³ | —³ | —¹ |
| mm/min [μm] | | | | | | | |
| UV Transmission of | 94.5 | 0.9 | 91.6 | 1.5 | 89.2 | 2.1 | 0.1 |
| plasticizer at 365 nm | | | | | | | |
| 5 wt % in n-hexane [%] | | | | | | | |
| Backside exposure [s] | 45 | 56 | 55 | 79 | 80 | 185 | - |
| | | | | | | | 1 |
| Light transmission [%] | 100 | 65 | 97 | 56 | 92 | 60 | 15 |
| Depth 400 μmnegative dot | 216 | —² | 207 | —² | 220 | —² | —² |
| [μm] | | | | | | | |

| | H | I | J |
|---|---|---|---|
| Plasticizer | Linseed oil | Linseed | Linseed oil |
| | Firnis | oil cold | Equipur |
| | | pressed | |
| Cliche thickness [μm] | 1202 | 1167 | 1205 |
| Washout speed [mm/min] | 210 | 210 | 210 |
| Washout time [min] | 3.7 | 3.7 | 3.7 |
| Washout depth 200 | 947 | —³ | 951 |
| mm/min [μm] | | | |
| UV Transmission of | 27.9 | 74.5 | 57.6 |
| plasticizer at 365 nm | | | |
| 5 wt % in n-hexane [%] | | | |
| Backside exposure [s] | 151 | 94 | 110 |
| Light transmission [%] | 55 | 66 | 57 |
| Depth 400 μm negative dot | 213 | 217 | 225 |
| [μm] | | | |

¹plate development not possible with the procedure described in the example due to inhomogeneity of the raw plate,
²irradiation through mask layer not possible due to lacking LAMS adhesion. Non-crosslinked areas for backside exposure and washout tests were obtained by covering the raw plate with a metal plate during UV-irradiation.
³washout completely down to carrier foil,
⁴plate cloudy, which can negatively influence the backside exposure.

From the results in table 7 it can be concluded, that the quality of the vegetable oil is important for its use as plasticizer. If the quality of the oil is not sufficient, the production of a good printing plate within the scope of the invention is difficult. Among other values, the UV transmission and light transmission might be used to evaluate the quality of the vegetable oil and its suitability for the invention. A high UV and light transmission are preferred. The UV transmission and light transmission are dependent on many factors apart from the general type of crop.

### Properties of the Plasticizers:

The mineral oil (CAS 8042-47-5) used has a kinematic viscosity at 40° C. 70 mm²/s.

The polybutadiene used has a molecular weight of Mw<10000 g/mol and ˜34% 1,2-vinyl groups (example 2, example 5), a molecular weight of Mw˜5000 g/mol and 1% 1,2-vinyl groups (example 3), a molecular weight of Mw<3000 g/mol and 15-25% 1,2-vinyl groups (example 4).

The rapeseed oil has a density at 20° C. of 0.916-0.923 g/cm³, a refractive index at 20° C. of 1.470-1.474, an iodine value (g iodine/100 g) of 105-126, an acid value (mg KOH/g) below 0.5, and a saponification value (mg KOH/g) of 180-195.

The rapeseed oil aged was obtained by heating the same batch of rapeseed oil as used for the other experiments to 160° C. for 19 h.

The linseed oil aged, sunflower oil aged and soybean oil aged was obtained by heating the same batches of the respective oils as used for the other experiments to 160° C. for 19 h under the influence of air.

The linseed oil aged 5 h was obtained by heating linseed oil to 160° C. for 5 h under the influence of air.

“Linseed oil Firnis” has a density at 20° C. of 0.95 g/cm² and was obtained from MEYER-CHEMIE GmbH & Co. KG without further specification.

Linseed oil Equipur was obtained from VETRIPHARM GmbH without further specification.

Linseed oil cold pressed was obtained from Makana Produktion und Vertrieb GmbH without further specification.

The sunflower oil has a density at 20° C. of 0.919-0.925 g/cm³, a refractive index at 20° C. of 1.473-1.476, an iodine value (g iodine/100 g) of 120-140, an acid value (mg KOH/g) below 0.5, and a saponification value (mg KOH/g) of 184-194.

The HO (high oleic) sunflower oil has a density at 20° C. of 0.912-0.920 g/cm³, a refractive index at 20° C. of 1.464-1.474, an iodine value (g iodine/100 g) of 78-90, an acid value (mg KOH/g) below 0.4, and a saponification value (mg KOH/g) of 187-197.

The soybean oil has a density at 20° C. of 0.916-0.922 g/cm³, a refractive index at 20° C. of 1.465-1.475, an iodine value (g iodine/100 g) of 120-141, an acid value (mg KOH/g) below 0.5, and a saponification value (mg KOH/g) of 180-200.

The palm oil has a melting point of 33-42° C., a refractive index at 40° C. of 1.450-1.460, an iodine value (g iodine/100 g) of 50-57, an acid value (mg KOH/g) below 0.4, and a saponification value (mg KOH/g) of 190-210.

The palm kernel oil has a melting point of 25-30° C., a refractive index at 40° C. of 1.448-1.452, an iodine value (g iodine/100 g) of 13-23, an acid value (mg KOH/g) below 0.4, and a saponification value (mg KOH/g) of 230-254.

The coconut oil has a melting point of 20-28° C., a refractive index at 40° C. of 1.448-1.451, an iodine value (g iodine/100 g) of 7-12, and an acid value (mg KOH/g) below 0.4.

The MCT oil (medium chain triglycerides 60/40) has a density at 20° C. of 0.930-0.960 g/cm³, a refractive index at 20° C. of 1.440-1.452, an iodine value (g iodine/100 g) of 0-1 and an acid value (mg KOH/g) below 0.2, and a saponification value (mg KOH/g) of 325-345.

The linseed oil has a density at 20° C. of 0.924-0.931 g/cm³, a refractive index at 20° C. of 1.478-1.483, an iodine value (g iodine/100 g) of 170-203 and an acid value (mg KOH/g) below 0.5, a saponification value (mg KOH/g) of 186-194, and a Gardner color below 6.0.

The castor oil has a density at 20° C. of 0.955-0.968 g/cm³, a refractive index at 20° C. of 1.478-1.480, an acid value (mg KOH/g) below 2, and a Gardner color below 4.0.

In the above, the invention has been disclosed using examples thereof. However, the skilled person will understand that the invention is not limited to these examples and that many more examples are possible without departing from the scope of the present invention, which is defined by the appended claims and equivalents thereof.

1-24. (canceled)

25. A relief precursor comprising:
a) a dimensionally stable support; and
b) at least one photopolymer layer comprising at least one binder, at least one photoinitiator or photoinitiating system, at least one component with at least one unsaturated group and at least one plasticizer;
wherein the at least one plasticizer is a bio-based plasticizer, the plasticizer has a UV transmission at 365 nm of a solution of 5 wt % plasticizer in n-hexane of higher than 15%.

26. A relief precursor comprising:
a) a dimensionally stable support; and
b) at least one photopolymer layer comprising at least one binder, at least one photoinitiator or photoinitiating system, at least one component with at least one unsaturated group and at least one plasticizer;
wherein the at least one plasticizer is a bio-based plasticizer and wherein the concentration of the plasticizer in the photopolymer layer is in the range of from 10 up to 65 wt % and wherein the plasticizer has a UV transmission at 365 nm of a solution of 5 wt % plasticizer in n-hexane of higher than 30%.

27. The precursor of claim 25, wherein the bio-based plasticizer is a vegetable oil, a fatty acid and/or a fatty acid ester of mono- or polyfunctional alcohols.

28. The precursor of claim 25, wherein the relief precursor comprises a further layer, wherein the further layer is an adhesion layer below the support, an adhesion layer between the support and a photopolymer layer, a barrier layer, a laser ablatable layer and/or a protective layer or combinations thereof.

29. The precursor of claim 25, wherein the plasticizer has a UV transmission at 365 nm of a solution of 5 wt % plasticizer in n-hexane of higher than 50%.

30. The precursor of claim 25, wherein the plasticizer has a light transmission in comparison to medium-chain triglycerides (MCT)-oil (=100% transmission) of higher than 78%.

31. The precursor of claim 25, wherein the plasticizer has a Gardner color lower than 7 according to ISO 4630:2015.

32. The precursor of claim 25, wherein the plasticizer has a hydroxyl value according to ASTM D1957-86 below 430.

33. The precursor of claim 25, wherein the plasticizer has an iodine value according to ISO 3961:2018 below 150.

34. The precursor of claim 25, wherein the plasticizer has a Hansen solubility parameter δt in the range of 16.0 to 20.5.

35. The precursor of claim 25, wherein the concentration of the plasticizer in the photopolymer layer is in the range of from 20 up to 60 wt %, based on the total weight of the photopolymer layer.

36. A method for producing a relief structure comprising the following steps:
a) providing of a relief precursor comprising a dimensionally stable support, a photopolymer layer comprising at least one binder, at least one photoinitiator or photoinitiating system, at least one component with at least one unsaturated group, and at least one plasticizer wherein the at least one plasticizer is a bio-based plasticizer, the plasticizer has a UV transmission at 365 nm of a solution of 5 wt % plasticizer in n-hexane of higher than 15%;
b) imaging the relief precursor by ablation of a mask layer, by exposure through mask or by direct imaging;
c) exposing the imaged relief precursor with electromagnetic radiation to cure the imaged areas;
d) removing of the non-cured areas; and
e) optionally performing one or more steps of post treatment, post exposure, and/or detackifying.

37. The method of claim 36, wherein the bio-based plasticizer is a vegetable oil, a fatty acid and/or a fatty acid ester of mono- or polyfunctional alcohols.

38. The method of claim 36, wherein the plasticizer has a UV transmission at 365 nm of a solution of 5 wt % plasticizer in n-hexane of higher than 30%.

39. The method of claim 36, wherein the plasticizer has a Gardner color lower than 7 according to ISO 4630:2015.

40. The method of claim 36, wherein the plasticizer has a hydroxyl value according to ASTM D1957-86 below 430.

41. The method of claim 36, wherein the plasticizer has an iodine value according to ISO 3961:2018 below 200.

42. The method of claim 36, wherein the plasticizer has a Hansen solubility parameter δt in the range of 16 to 20.5.

43. The method of claim 36, wherein the concentration of the plasticizer in the photopolymer layer is in the range of from 3 up to 70 wt %, based on the total weight of the photopolymer layer.

44. The method of claim 36, wherein removal of the non-cured areas of the precursor is performed by treatment with heat and a developing material configured to adsorb non-cured material.

45. The method of claim 36, wherein in step d) the precursor is heated to a temperature in the range of from 70 to 200° C.

46. The method of claim 36, wherein in step d) the precursor is treated with a developing liquid to dissolve non-cured material.
